(19) United States
(12) Patent Application Publication
(10) Pub. No.: US 2025/0364615 A1
(43) Pub. Date: Nov. 27, 2025

(54) SYSTEM AND METHOD

(71) Applicant: TOYOTA JIDOSHA KABUSHIKI KAISHA, Toyota-shi (JP)

(72) Inventor: Takuya MATSUYAMA, Miyoshi-shi (JP)

(73) Assignee: TOYOTA JIDOSHA KABUSHIKI KAISHA, Toyota-shi (JP)

(21) Appl. No.: 19/057,122

(22) Filed: Feb. 19, 2025

(30) Foreign Application Priority Data
May 22, 2024 (JP) 2024-083216

(51) Int. Cl. H01M 10/48; H01M 4/38; H01M 10/0585

(52) U.S. Cl. CPC H01M 10/48; H01M 4/386; H01M 10/0585

(57) ABSTRACT

A system includes a detection apparatus and a determination apparatus. The all-solid-state battery includes a positive electrode layer, a solid electrolyte layer, and a negative electrode layer in the stated order. The negative electrode layer includes a negative-electrode active material. The detection apparatus is configured to detect a state quantity. The state quantity includes at least one of an external dimension of the all-solid-state battery and confining pressure applied to the all-solid-state battery. The determination apparatus is configured to determine that an abnormality has occurred in the all-solid-state battery when the fluctuation of the state quantity turns to an increasing trend from a decreasing trend.

### CROSS-REFERENCE TO RELATED APPLICATION

This application claims priority to Japanese Patent Application No. 2024-083216 filed on May 22, 2024, incorporated herein by reference in its entirety.

### BACKGROUND

### 1. Technical Field

The present disclosure relates to a system and a method.

### 2. Description of Related Art

Japanese Unexamined Patent Application Publication No. 2019-179731 (2019-179731 A) discloses an all-solid-state-battery negative electrode containing silicon.

### SUMMARY

A liquid battery includes an electrolytic solution (liquid). A method of determining the state of a liquid battery by monitoring various state quantities in the liquid battery has been proposed. An all-solid-state battery consists only of solid. The all-solid-state battery is different from the liquid battery in terms of the form of deterioration. There is a fear that the state of the all-solid-state battery cannot be suitably determined in accordance with a method similar to that for the liquid battery.

An object of the present disclosure is to provide a system that determines the state of an all-solid-state battery.

Technical configurations and effects of the present disclosure are described below. However, the working mechanism of the present disclosure includes presumption. The working mechanism does not limit the technical scope of the present disclosure.

1. One aspect of the present disclosure is a “system” that determines a state of an all-solid-state battery. The system includes a detection apparatus and a determination apparatus. The all-solid-state battery includes a positive electrode layer, a solid electrolyte layer, and a negative electrode layer in the stated order. The negative electrode layer includes a negative-electrode active material. The detection apparatus is configured to detect a state quantity. The state quantity includes at least one of an external dimension of the all-solid-state battery and confining pressure applied to the all-solid-state battery. The determination apparatus is configured to determine that an abnormality has occurred in the all-solid-state battery when a fluctuation of the state quantity turns to an increasing trend from a decreasing trend.

The state quantity in the present disclosure includes at least one of an external dimension (for example, thickness) and confining pressure. It is conceived that there is a positive correlation between the external dimension and the confining pressure when the battery is confined by the confining member. It is conceived that the fluctuation of the external dimension and the fluctuation of the confining pressure show the same trend.

In general, the fluctuation of the state quantity of a liquid battery steadily increases. In other words, the liquid battery may continuously expand as the number of times of cycles increases. In the liquid battery, the negative electrode layer is porous. An electrolytic solution permeates into gaps of the negative electrode layer. The negative-electrode active material may expand at the time of charging and may shrink at the time of discharging. Even when the electrolytic solution is consumed, the electrolytic solution may permeate into the gaps again when the electrolytic solution reacts with the negative-electrode active material. Therefore, it is conceived that rearrangement of the negative-electrode active materials (particles), generation of gas, and formation of a solid electrolyte interphase (SEI) film may continuously occur in the negative electrode layer of the liquid battery. It is conceived that the liquid battery continuously expands as a result.

Meanwhile, according to a new insight of the present disclosure, the fluctuation of the state quantity in the all-solid-state battery may turn to an increasing trend from a decreasing trend. The all-solid-state battery consists only of solid. The negative electrode layer is dense. The solid electrolyte does not have fluidity. Therefore, it is conceived that rearrangement of the negative-electrode active materials (particles), generation of gas, and formation of a solid electrolyte interphase (SEI) film do not easily occur in the negative electrode layer of the all-solid-state battery in a sustainable way. The negative-electrode active material may greatly expand at the time of initial charging. The expansion amount of the negative-electrode active material at the time of charging may gradually decrease as a result of repeating charging and discharging. Therefore, it is conceived that the fluctuation of the thickness of the all-solid-state battery shows a decreasing trend.

However, for example, when peeling occurs at an interface between the negative electrode layer and the solid electrolyte layer, conduction paths (ion conduction paths and electron conduction paths) locally and rapidly decrease. In other words, unevenness in the negative electrode reaction occurs in the in-plane direction of the negative electrode layer. A negative-electrode active material that has lost conduction paths can no longer contribute to the negative electrode reaction. Therefore, current concentrates on a negative-electrode active material that still has a conduction path. The negative-electrode active material on which current concentrates may be charged more excessively than expected. When the negative-electrode active material expands more excessively than expected, it is conceived that the fluctuation of the thickness of the all-solid-state battery turns to an increasing trend. There is a fear that capacity deterioration of the all-solid-state battery may rapidly progress as a result of the unevenness in the negative electrode reaction expanding thereafter.

In other words, it is conceived that a turning point at which the fluctuation of the state quantity turns to an increasing trend from a decreasing trend is a turning point at which the state of the all-solid-state battery turns to “abnormal” from “normal”. By determining that an abnormality has occurred in the all-solid-state battery when the fluctuation is on an increasing trend, appropriate measures may be performed before rapid capacity deterioration occurs.

2. The system according to term “1” described above may include the following configuration, for example. The negative-electrode active material includes silicon (Si).

The negative-electrode active material including Si tends to expand by an especially great amount when being excessively charged. When the negative-electrode active material includes Si, there is a fear that unevenness in the negative electrode reaction may occur, and hence capacity deterioration may acceleratingly progress. Therefore, it is conceived that the system of “1” described above is particularly effective when the negative-electrode active material includes Si.

3. The system according to term “1” or “2” described above may include the following configuration, for example. The determination apparatus is configured to determine that the fluctuation of the state quantity is on an increasing trend when a relationship of 1.05≤(A₁/A₀) is satisfied. Here, A₀ represents an initial value of the state quantity. Further, A₁ represents a current value of the state quantity.

The current value (A₁) of the state quantity becomes greater than the initial value (A₀) as a result of the state quantity continuing to increase after the fluctuation of the state quantity turns to an increasing trend from a decreasing trend. For example, it may be determined that the fluctuation is on an increasing trend when a ratio (A₁/A₀) of the current value to the initial value becomes 105% or more.

4. The system according to any one of terms “1” to “3” described above may include the following configuration, for example. The detection apparatus is configured to detect the state quantity at the time of charging of the all-solid-state battery. The determination apparatus is configured to monitor the fluctuation of the state quantity in accordance with an increase in the number of times of charging.

The negative-electrode active material expands at the time of charging. The determination precision is expected to improve by measuring the state quantity at the time of charging. The horizontal axis of the fluctuation is freely-selected as long as the horizontal axis indicates a usage history of the battery. For example, fluctuation in accordance with an increase in the number of times of charging may be monitored. Counting of the number of times of charging may be simple.

5. One aspect of the present disclosure is a “method” that determines a state of an all-solid-state battery. The method includes (a) and (b) described below.
(a) Detecting a state quantity.
(b) Determining that an abnormality has occurred in the all-solid-state battery when a fluctuation of the state quantity turns to an increasing trend from a decreasing trend.

The all-solid-state battery includes a positive electrode layer, a solid electrolyte layer, and a negative electrode layer in the stated order. The negative electrode layer includes a negative-electrode active material. The negative-electrode active material includes silicon. The state quantity includes at least one of an external dimension of the all-solid-state battery and confining pressure applied to the all-solid-state battery. The state quantity is detected at the time of charging of the all-solid-state battery. The fluctuation of the state quantity in accordance with an increase in the number of times of charging is monitored. Determination that the fluctuation of the state quantity is on an increasing trend is made when a relationship of 1.05≤(A₁/A₀) is satisfied. Here, A₀ represents an initial value of the state quantity. Further, A₁ represents a current value of the state quantity.

One embodiment of the present disclosure (may hereinafter be abbreviated as the “present embodiment”) and one example of the present disclosure (may hereinafter be abbreviated as the “present example”) are described below. However, the present embodiment and the present example do not limit the technical scope of the present disclosure. The present embodiment and the present example are exemplifications in every respect. The present embodiment and the present example are non-limiting. The technical scope of the present disclosure encompasses all modifications made within the scope and spirit equivalent to those described in the claims. For example, a case in which freely-selected configurations are extracted from the present embodiment and those configurations are combined in a freely-selected manner is planned from the beginning.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram showing one example of a system in a present embodiment;

FIG. 2 is an outline flowchart showing one example of a method in the present embodiment;

FIG. 3 is a graph showing one example of the fluctuation of the state quantity; and

FIG. 4 is a conceptual diagram showing an experiment method.

### DETAILED DESCRIPTION OF EMBODIMENTS

### Terms and Phases

Expressions of “comprise”, “include”, and “have” and variations thereof are open-end expressions. Configurations expressed in an open-end manner may or may not further include additional elements in addition to essential elements. The wording of “consist of” is a closed expression. However, a configuration may include impurities that are normally accompanying and additional elements that are unrelated to the target technology even when the configuration is expressed in a closed manner. The wording of “substantially consist of” is a semi-closed expression. In configurations expressed in a semi-closed manner, addition of elements that substantially do not affect basic and novel characteristics of the target technology is allowed.

Expressions of “may” and the like are used by an allowing meaning, that is, “the meaning of having a possibility” and not by a mandatory meaning, that is, “the meaning of must”.

The order of execution of a plurality of steps, movements, operations, and the like included in various methods is not limited to the described order unless otherwise stated. For example, a plurality of steps may simultaneously progress. For example, the order of a plurality of steps may be switched.

For example, the expression of “at least one of A and B” includes the expressions of “A or B” and “A and B”. The expression of “at least one of A and B” may also be described as “A and/or B”.

A “state of charge (SOC)” indicates a rate obtained by subtracting a rate of a discharged electricity amount from a state in which a battery is fully charged. The SOC of a fully charged state is 100%. The SOC of a fully discharged state is 0%.

The “confining pressure” is obtained by dividing a force (load) applied to the battery by an area of a surface receiving the force. The confining pressure may be obtained by a relational expression of “σ=E/ε”, for example. Here, “σ” represents the confining pressure. Further, “ε” represents a displacement amount (decrease amount) between the thickness of the battery before the confining member is attached and the thickness of the battery after the confining member is attached. Further, “E” represents the Young's modulus of the battery.

### System

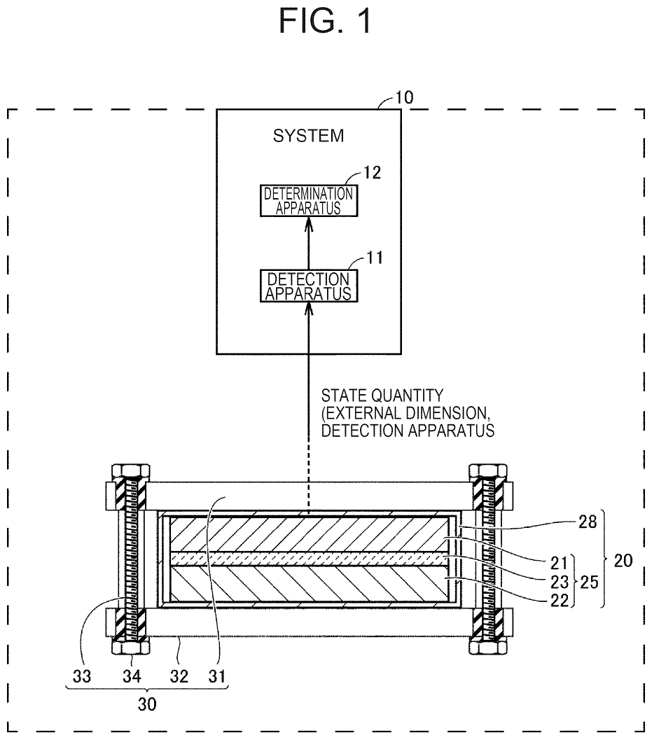

FIG. 1 is a block diagram showing one example of a system in a present embodiment. “The system in the present embodiment” may hereinafter be abbreviated as the “present system”. A present system 10 determines the state of an all-solid-state battery 20. The present system 10 includes a detection apparatus 11 and a determination apparatus 12. The apparatuses may be indivisibility integrated or may be independent of each other. The all-solid-state battery 20 may be included in the present system 10 or may be independent of the present system 10. Confining pressure may be applied to the all-solid-state battery 20 by a confining member 30. The confining member 30 may be included in the present system 10 or may be independent of the present system 10.

The purpose of the present system 10 is freely selected. The present system 10 may be mounted on a vehicle, for example. In other words, the present system 10 may operate on board. The vehicle may be a battery electric vehicle (BEV), a hybrid electric vehicle (HEV), or a plug-in hybrid electric vehicle (PHEV), for example.

The present system 10 may operate off board. The present system 10 may operate in the home of a vehicle user, a charging apparatus owned by the vehicle user, or a charging stand (also referred to as a charging station, a charging spot, and the like), for example.

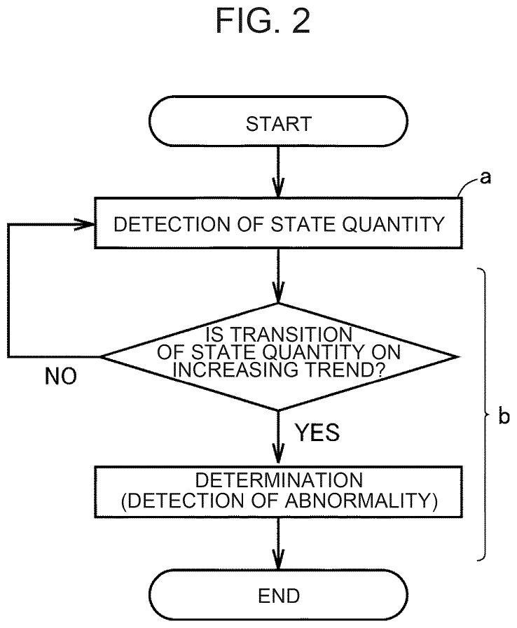

FIG. 2 is an outline flowchart showing one example of a method in the present embodiment. “The method in the present embodiment” may hereinafter be abbreviated as the “present method”. The present system 10 may perform the present method.

### Detection Apparatus

The detection apparatus 11 detects the state quantity. In other words, the present method includes detecting the state quantity. The state quantity includes at least one of the external dimension of the all-solid-state battery 20 and the confining pressure applied to the all-solid-state battery 20. The external dimension may include at least one selected from a group consisting of the thickness, the width, and the length, for example.

The detection apparatus 11 may include various sensors. The sensor measures the state quantity. For example, when the detection target is “thickness”, the detection apparatus 11 may include various displacement sensors. The displacement sensor may measure the dimension by a freely-selected method. The displacement sensor may be attached to the confining member 30 (described later), for example. The displacement sensor may be a position sensitive device (PSD) type, a charge coupled device (CCD) type, a laser type, an ultrasonic type, a differential transformer type, or a magnetic detection type, for example.

For example, when the detection target is the “confining pressure”, the detection apparatus 11 may include various pressure sensors. The pressure sensors may include a load cell and a pressure measurement film (tactile sensor), for example. For example, the load cell may be installed in contact with the confining member 30. For example, the pressure measurement film may be interposed between the confining member 30 and the all-solid-state battery 20. The pressure measurement film may measure the pressure on the entire plane of a contact surface between the confining member 30 and the all-solid-state battery 20. An arithmetic mean value of the pressure measured by each part of the pressure measurement film may be obtained. The pressure measurement film may locally measure the pressure. For example, the pressure on a central portion out of the contact surface may be measured.

The detection apparatus 11 may detect the state quantity at a freely-selected timing. The detection apparatus 11 may detect the state quantity at a particular timing. The state quantity may be detected at the time of charging, for example. For example, the state quantity may be detected in the home of the vehicle user at the time of charging during the night. For example, the state quantity may be detected at the time of charging in a charging station.

The determination precision is expected to improve as a result of the state quantity being detected in a high SOC. The SOC in which the state quantity is detected may be 50% or more, 60% or more, 70% or more, 80% or more, 90% or more, or 95% or more, for example. The SOC in which the state quantity is detected may be 100% or less, 95% or less, or 90% or less, for example.

The detection apparatus 11 may include an input apparatus (not shown), for example. A detection value of the sensor may be input to the input apparatus. The input apparatus may be connected to a storage apparatus (described later), for example. The detection value may be accumulated in the storage apparatus.

### Determination Apparatus

The determination apparatus 12 determines that an abnormality has occurred in the all-solid-state battery 20 when the fluctuation of the state quantity turns to an increasing trend from a decreasing trend. In other words, the present method includes determining that an abnormality has occurred in the all-solid-state battery 20 when the fluctuation of the state quantity turns to an increasing trend from a decreasing trend.

The determination apparatus 12 may include a storage apparatus and an arithmetic unit, for example. The determination apparatus 12 acquires the state quantity detected by the detection apparatus 11, for example. The storage apparatus may accumulate the state quantity at each detection time point. For example, the arithmetic unit may generate a fluctuation graph (two-dimensional graph) in which the horizontal axis is each detection time point and the vertical axis is the state quantity based on history data of the state quantity.

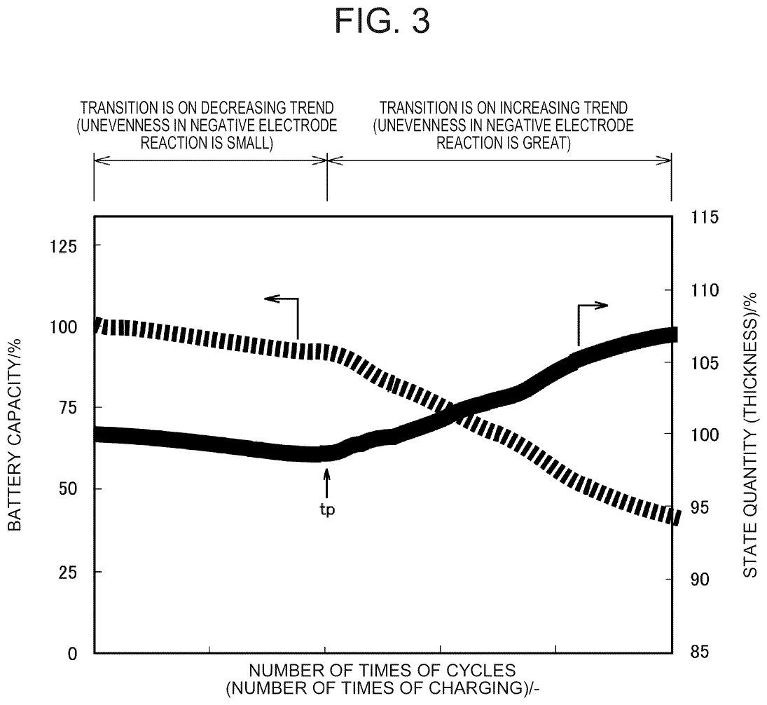

FIG. 3 is a graph showing one example of the fluctuation of the state quantity. In FIG. 3, the thickness is measured as one example of the state quantity. In FIG. 3, the fluctuation of the battery capacity is also shown as a reference. The horizontal axis of the graph is a value indicating the usage history of the all-solid-state battery 20. The horizontal axis may be the number of times the state quantity is detected, the number of times of cycles, the elapsed time, the elapsed days, the number of times of charging, or the number of times of discharging, for example. The number of times of charging may be the same value as the number of times of cycles. The number of times of charging may be the number of times a predetermined SOC is reached, for example. The predetermined SOC may be 50% or more, 60% or more, 70% or more, 80% or more, 90% or more, or 95% or more, for example. The predetermined SOC may be 100% or less, 95% or less, or 90% or less, for example.

In FIG. 3, the number of times of cycles is set as the horizontal axis as one example. At the start of usage, the thickness gradually decreases as the number of times of cycles increases. In other words, the fluctuation is on a decreasing trend. As a result of an increase in the number of times of cycles, the thickness reaches a turning point (tp). When the turning point (tp) is passed through, the thickness starts to increase. In other words, at the turning point (tp), the fluctuation turns to an increasing trend from a decreasing trend.

When the turning point (tp) is passed through, the battery capacity starts to rapidly decrease. It is conceived that unevenness in the negative electrode reaction is small in a period of time from the start of usage to the turning point (tp). It is conceived that unevenness in the negative electrode reaction increases at the turning point (tp) and thereafter. For example, there is a fear that partial peeling may have occurred at an interface between a negative electrode layer 22 and a solid electrolyte layer 23.

The determination apparatus 12 may monitor the fluctuation of the state quantity. The determination apparatus 12 may monitor fluctuation of the state quantity in accordance with the increase in the number of times of charging, for example. The determination apparatus 12 may determine whether the fluctuation is on a decreasing trend or on an increasing trend based on results of five consecutive times of detection of the state quantity, for example. The determination apparatus 12 may determine that the fluctuation is on a decreasing trend when the detection value has decreased from last time for three times or more in the results of five consecutive times of detection of the state quantity, for example. The determination apparatus 12 may determine that the fluctuation is on an increasing trend when the detection value has increased from last time for three times or more in the results of five consecutive times of detection of the state quantity, for example.

For example, the arithmetic unit may detect a local minimum value of a fluctuation curve by differentiating the fluctuation curve. For example, a local minimum point of the fluctuation curve may be considered to be the turning point (tp). It may be determined that the fluctuation has entered an increasing trend when the turning point (tp) is detected.

For example, it may be determined that the fluctuation is on an increasing trend when a relationship of “1.05≤(A₁/A₀)” is satisfied. Here, “A₀” represents an initial value (for example, the initial thickness, the initial confining pressure) of the state quantity. Further, “A₁” represents a current value of the state quantity.

For example, it may be determined that the fluctuation is on an increasing trend when a relationship of “1.04≤(A₁/A₀)”, “1.03≤(A₁/A₀)”, or “1.02≤(A₁/A₀)” is satisfied. For example, the expression of “1.05=(A₁/A₀)” may have the same meaning as 105% in FIG. 3.

The determination apparatus 12 determines that an abnormality has occurred in the all-solid-state battery 20 when the fluctuation is on an increasing trend. The determination apparatus 12 may output a determination result (the occurrence of an abnormality). The determination apparatus 12 may notify a user of the occurrence of an abnormality. The determination apparatus 12 may prompt the user to replace the all-solid-state battery 20, for example.

### Other Apparatuses

The present system 10 may further include a display apparatus (not shown), for example. For example, the display apparatus may notify a user of a determination result (the occurrence of an abnormality). The display apparatus may include a display and a speaker, for example. For example, the determination apparatus 12 may include the display apparatus.

The present system 10 may further include a control apparatus (not shown), for example. The control apparatus may control each apparatus included in the present system 10. For example, the control apparatus may change the use conditions of the all-solid-state battery 20 based on the determination result of the determination apparatus 12. The control apparatus may change at least one selected from a group consisting of an upper limit charging current, an upper limit discharging current, an upper limit SOC, a lower limit SOC, and confining pressure, for example, after the occurrence of an abnormality. For example, the upper limit charging current (maximum current) may be reset to a value lower than the initial value. For example, the upper limit SOC may be reset to a value lower than the initial value. For example, there is a possibility that rapid capacity deterioration may be alleviated by the change of the use conditions.

### All-Solid-State Battery

The all-solid-state battery 20 may have a freely-selected external form. The all-solid-state battery 20 may have a plate-like external form, for example. The all-solid-state battery 20 may include an electricity generation element 25 and an exterior body 28, for example. The exterior body 28 may accommodate the electricity generation element 25. The exterior body 28 may have a freely-selected form. The exterior body 28 may be a case made of metal, for example. The exterior body 28 may be a pouch made of an Al laminate film, for example.

The electricity generation element 25 includes a positive electrode layer 21, the solid electrolyte layer 23, and the negative electrode layer 22 in the stated order. The electricity generation element 25 may have a freely-selected structure. The electricity generation element 25 may have a monopolar structure or a bipolar structure, for example. For example, the electricity generation element 25 may be formed as a result of the positive electrode layer 21 and the negative electrode layer 22 being alternately laminated with the solid electrolyte layer 23 being interposed therebetween.

The positive electrode layer 21 may include a positive-electrode active material layer and a positive-electrode current collector, for example. The positive-electrode active material layer may be disposed on one side of the positive-electrode current collector or on both sides of the positive-electrode current collector, for example. The positive-electrode current collector may include an aluminum (Al) foil or an Al alloy foil, for example.

The positive-electrode active material layer includes a positive-electrode active material. The positive-electrode active material may be powder. The positive-electrode active material may reversibly store therein lithium (Li). The positive-electrode active material may include freely-selected components. The positive-electrode active material may include lithium nickel cobalt manganese oxide (NCM), lithium nickel cobalt aluminum oxide (NCA), and lithium ferrous phosphate (LFP), for example. The positive-electrode active material may be covered with an oxide film. The oxide film may include niobium (Nb), titanium (Ti), phosphorus (P), and boron (B), for example.

The positive electrode layer 21 includes a solid electrolyte. The solid electrolyte may be powder. The solid electrolyte may form an ion conduction path. The solid electrolyte may include a sulfide solid electrolyte, for example. The sulfide solid electrolyte may include at least one type selected from a group consisting of an amorphous phase, a crystalline phase, and a glass ceramics (crystallized glass) phase. The crystalline phase may be an argyrodite type or an LGPS type, for example. The sulfide solid electrolyte includes Li and sulfur(S). The sulfide solid electrolyte may further include freely-selected components in addition to Li and S. The sulfide solid electrolyte may have a composition expressed by the following general expression, for example.

yLiI−zLiBr−(100−y−z)[xLi₂S−(1−x)P₂S₅]

Here, x may be from 0.5 to 0.9, for example. For example, y may be from 0 to 30. For example, z may be from 0 to 30. Here, the composition becomes “10LiI−90 [0.75Li₂S−0.25P₂S₅]” when x=0.75, y=10, and z=0 are satisfied, for example. The composition indicates that the mixing ratio (mass ratio) of each raw material is “LiI:LiBr:(0.75Li₂S−0.25P₂S₅)=10:0:90”. Here, “0.75Li₂S−0.25P₂S₅” indicates that the mixing ratio of each raw material is “Li₂S:P₂S₅=0.75:0.25”. Here, “0.75Li₂S−0.25P₂S₅” may be expressed as “Li₃PS₄”, for example. The sulfide solid electrolyte may be synthesized by a mechanochemical method, for example.

The positive electrode layer 21 may further include a conductive material. The conductive material may form an electron conduction path. The conductive material may include at least one type selected from a group consisting of acetylene black (AB), vapor-grown carbon fiber (VGCF), a carbon nanotube (CNT), and graphene flakes (GF), for example. The positive electrode layer 21 may further include a binder. The binder may couple solid components. The binder may include a polyvinylidene fluoride (PVdF), poly (vinylidene fluoride-co-hexafluoropropylene) (PVdF-HFP), and styrene-butadiene rubber (SBR), for example.

The negative electrode layer 22 may include a negative-electrode active material layer and a negative-electrode current collector, for example. The negative-electrode active material layer may be disposed on one side of the negative-electrode current collector or on both sides of the negative-electrode current collector, for example. The negative-electrode current collector may include a copper (Cu) foil, a Cu alloy foil, a nickel (Ni) foil, or a Ni alloy foil, for example.

The negative-electrode active material layer includes a negative-electrode active material. The negative-electrode active material may be powder. The negative-electrode active material may reversibly store therein Li. The negative-electrode active material may include freely-selected components. The negative-electrode active material may include at least one type selected from a group consisting of graphite, soft carbon, hard carbon, Si, Li silicate, SiO, Si—C, a Si-based alloy, Sn, SnO, a Sn-based alloy, and Li₄Ti₅O₁₂, for example.

For example, “Si” may be amorphous or crystalline. Further, Si may include a freely-selected crystal phase. For example, Si may include at least one type selected from a group consisting of a diamond-type crystal phase, a clathrate I-type crystal phase, and a clathrate II-type crystal phase. For example, “SiO” may have a composition expressed by a general expression of “SiOₓ (0.5<x<1.5)”. Here, “Si—C” represents a composite material of carbon (C) and Si. For example, Si particulates may be dispersed in carbon particles. For example, Si particulates may be dispersed in graphite particles. For example, Li silicate particles may be covered with a carbon material (an amorphous carbon and the like).

The negative-electrode active material layer may further include a solid electrolyte, a conductive material, and a binder in addition to the negative-electrode active material. The conductive material included in the negative-electrode active material layer and the conductive material included in the positive-electrode active material layer may be the same or different.

The solid electrolyte layer 23 is interposed between the positive-electrode active material layer and the negative-electrode active material layer. The solid electrolyte layer 23 spaces the positive-electrode active material layer apart from the negative-electrode active material layer. The solid electrolyte layer 23 may be rephrased as a “separator layer”, for example. The solid electrolyte layer 23 includes a solid electrolyte. The solid electrolyte layer 23 may further include a binder, for example. The solid electrolyte and the binder may be the same or different between the solid electrolyte layer 23, the positive-electrode active material layer, and the negative-electrode active material layer.

### Confining Member

The confining member 30 applies confining pressure (pressure) to the all-solid-state battery 20. The pressure may be applied along the thickness direction of the all-solid-state battery 20. The thickness direction of the all-solid-state battery 20 may be substantially the same direction as the laminated direction of the positive electrode layer 21, the solid electrolyte layer 23, and the negative electrode layer 22.

The confining member 30 may have a freely-selected structure. The confining member 30 may be configured by a single member or may be configured by a plurality of members, for example. The confining member 30 may have a band shape, for example. The confining member 30 may include a first plate 31, a second plate 32, bolts 33, and nuts 34, for example. The all-solid-state battery 20 is disposed between the first plate 31 and the second plate 32. Through-holes are provided in the first plate 31 and the second plate 32. For example, the through-holes may be provided in four corners of each plate in plan view. The bolts 33 are inserted through the through-holes. The nuts 34 are screwed together with the bolts 33. The first plate 31 and the second plate 32 apply pressure to the all-solid-state battery 20 as a result of the nuts 34 being fastened. In other words, confining pressure is generated. The magnitude of the confining pressure may be adjusted by a fastening torque of the nuts 34, for example. The confining member 30 may be made of metal or may be made of resin, for example.

The confining member 30 has a fracture stress. The “fracture stress” indicates a critical stress that the confining member 30 may withstand without breaking when a force applied to the confining member 30 gradually increases. The confining member 30 receives a reaction force from the all-solid-state battery 20. When the state quantity continues to increase after the fluctuation of the state quantity turns to an increasing trend, there is a fear that the reaction force may exceed the fracture stress of the confining member 30. The damage on the confining member 30 may be avoided as a result of the determination apparatus 12 determining the occurrence of an abnormality before the reaction force reaches the fracture stress. In other words, for example, the confining member 30 may be configured such that the force applied to the confining member 30 becomes less than the fracture stress when a relationship of “(A₁/A₀)<1.05”, “(A₁/A₀)<1.04”, “(A₁/A₀)<1.03”, or “(A₁/A₀)<1.02” is satisfied. Here, “A₀” represents an initial value of the state quantity. Further, “A₁” represents a current value of the state quantity.

Preparation of all-Solid-State Battery

A first mixture is prepared as a result of mixing a positive-electrode active material (NCA), a sulfide solid electrolyte (10LiI−90 [0.75Li₂S−0.25P₂S₅]), a conductive material (VGCF), and a binder (PVdF). As a result of performing pressing on the first mixture, a positive-electrode active material layer is molded. The mixing ratio (mass ratio) of the first mixture is “positive-electrode active material:sulfide solid electrolyte:conductive material:binder=85:13:1.3:0.7”. The sulfide solid electrolyte includes a glass ceramics phase.

A second mixture is prepared as a result of mixing a sulfide solid electrolyte and a binder. As a result of performing pressing on the second mixture, a solid electrolyte layer (15 μm) is molded. The mixing ratio (mass ratio) of the second mixture is “sulfide solid electrolyte:binder=99.6:0.4”.

A third mixture is prepared as a result of mixing a negative-electrode active material (Si), a sulfide solid electrolyte, a conductive material, and a binder. As a result of performing pressing on the third mixture, a negative-electrode active material layer is molded. The mixing ratio (mass ratio) of the third mixture is “negative-electrode active material:sulfide solid electrolyte:conductive material:binder=53:41:4.5:1.5”. Here, D50 of Si is 2.5 μm. Further, “D50” represents a particle size with which the cumulative total becomes 50% in a particle size distribution (cumulative distribution) based on volume. The particle size distribution may be measured by a laser diffraction method.

A laminated body is formed as a result of laminating a positive-electrode current collector (Al foil), the positive-electrode active material layer, the solid electrolyte layer, the negative-electrode active material layer, and a negative-electrode current collector (Ni foil) in the stated order. As a result of performing pressing on the laminated body, an electricity generation element is formed. An electrode terminal is connected to the electricity generation element. The electricity generation element is accommodated in an exterior body. As a result, an all-solid-state battery is manufactured.

### Measurement of State Quantity

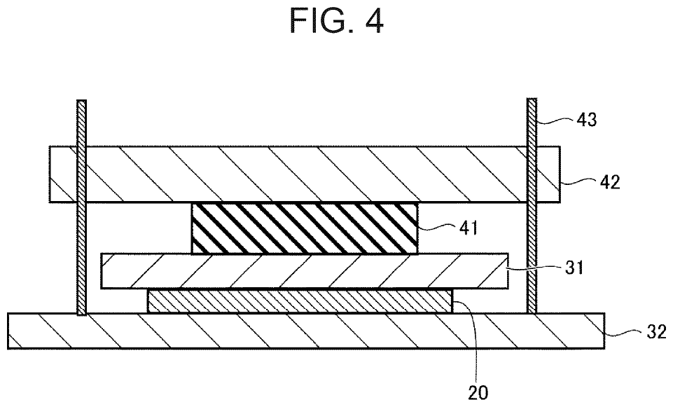

FIG. 4 is a conceptual diagram showing an experiment method. The first plate 31 and the second plate 32 are prepared. The all-solid-state battery 20 is disposed between the first plate 31 and the second plate 32. A load cell 41 and a weight 42 are disposed on the first plate 31. The confining pressure is adjusted by the weight 42. A displacement sensor 43 is attached to the first plate 31 and the second plate 32.

The initial charging and discharging of the all-solid-state battery 20 is performed in a constant temperature reservoir set to 40° C. In other words, the battery is charged from the SOC of 0% to the SOC of 100% by constant-current constant-voltage (CCCV) charging. Next, the battery is discharged from the SOC of 100% to the SOC of 0% by CCCV discharging. The current rate at the time of CC charging or CC discharging is 0.1 C. The cut-off current at the time of CV charging or CV discharging is 0.02 C. Here, “C” is a symbol representing the magnitude of a current rate. At the current rate of 1 C, the rated capacity of the battery flows for one hour.

After the initial charging and discharging, charging and discharging are repeated by CCCV charging and CCCV discharging. One round of the following operation is one cycle. The battery is charged from the SOC of 5% to the SOC of 95% by CCCV charging. The battery is discharged from the SOC of 95% to the SOC of 5% by CCCV discharging. The current rate at the time of CC charging or CC discharging is 0.2 C. The cut-off current at the time of CV charging or CV discharging is 0.02 C. The load cell 41 measures the pressure (confining pressure) at the SOC of 95% (upper limit SOC). The displacement sensor 43 measures the thickness at the SOC of 95%.

### Measurement Result

The fluctuation of the thickness is shown in FIG. 3. It is confirmed that the fluctuation of the thickness turns to an increasing trend from a decreasing trend.

What is claimed is:

1. A system that determines a state of an all-solid-state battery, the system comprising:
a detection apparatus; and
a determination apparatus, wherein:
the all-solid-state battery includes a positive electrode layer, a solid electrolyte layer, and a negative electrode layer in a stated order;
the negative electrode layer includes a negative-electrode active material;
the detection apparatus is configured to detect a state quantity;
the state quantity includes at least one of an external dimension of the all-solid-state battery and confining pressure applied to the all-solid-state battery; and
the determination apparatus is configured to determine that an abnormality has occurred in the all-solid-state battery when a fluctuation of the state quantity turns to an increasing trend from a decreasing trend.

2. The system according to claim 1, wherein the negative-electrode active material includes silicon.

3. The system according to claim 1, wherein the determination apparatus is configured to determine that the fluctuation of the state quantity is on an increasing trend when a relationship of 1.05≤(A₁/A₀) is satisfied, where A₀ represents an initial value of the state quantity and A₁ represents a current value of the state quantity.

4. The system according to claim 1, wherein:
the detection apparatus is configured to detect the state quantity at a time of charging of the all-solid-state battery; and
the determination apparatus is configured to monitor the fluctuation of the state quantity in accordance with an increase in the number of times of charging.

5. A method of determining a state of an all-solid-state battery, comprising:
(a) detecting a state quantity; and
(b) determining that an abnormality has occurred in the all-solid-state battery when a fluctuation of the state quantity turns to an increasing trend from a decreasing trend; wherein:
the all-solid-state battery includes a positive electrode layer, a solid electrolyte layer, and a negative electrode layer in a stated order;
the negative electrode layer includes a negative-electrode active material;
the negative-electrode active material includes silicon;
the state quantity includes at least one of an external dimension of the all-solid-state battery and confining pressure applied to the all-solid-state battery;
the state quantity is detected at a time of charging of the all-solid-state battery;
the fluctuation of the state quantity in accordance with an increase in the number of times of charging is monitored; and
determination that the fluctuation of the state quantity is on an increasing trend is made when a relationship of 1.05≤(A₁/A₀) is satisfied, where A₀ represents an initial value of the state quantity and A₁ represents a current value of the state quantity.
